(19) United States
(12) Patent Application Publication
(10) Pub. No.: US 2026/0223426 A1
(43) Pub. Date: Jul. 30, 2026

(54) MOMENTUM MATCHING FOR VAN DER WAALS CONTACTS BETWEEN TWO-DIMENSIONAL AND THREE-DIMENSIONAL HETEROGENEOUS MATERIALS

(71) Applicant: GEORGIA STATE UNIVERSITY RESEARCH FOUNDATION, INC., Atlanta, GA (US)

(72) Inventor: Sidong Lei, Marietta, GA (US)

(21) Appl. No.: 19/463,575

(22) Filed: Jan. 29, 2026

Related U.S. Application Data
(60) Provisional application No. 63/751,497, filed on Jan. 30, 2025.

(51) Int. Cl. H10D 64/01; H10D 62/80; H10D 64/62

(52) U.S. Cl. CPC H10D 64/0114; H10D 62/882; H10D 64/62

(57) ABSTRACT

A method of increasing electrical conductivity of a contact between a two-dimensional (2D) material and a three-dimensional (3D) material comprises introducing metallic scattering media at an interface between the 2D material and the 3D material. The metallic scattering media reduces momentum mismatch between charge carriers in the 2D material and charge carriers in the 3D material by providing transverse momentum to the charge carriers during quantum tunneling across a van der Waals gap at the interface.

### CROSS-REFERENCE TO RELATED APPLICATIONS

This application claims priority to U.S. Provisional Patent Application No. 63/751,497, filed Jan. 30, 2025, entitled “MOMENTUM MATCHING FOR 2D-3D HETEROGENEOUS OHMIC VAN DER WAALS CONTACT,” which is hereby incorporated by reference in its entirety.

### STATEMENT REGARDING FEDERALLY SPONSORED RESEARCH OR DEVELOPMENT

This invention was made with government support under 2105126 and 2238564 awarded by the National Science Foundation. The government has certain rights in the invention.

### BACKGROUND

The fabrication of electrical contacts on two-dimensional (2D) materials presents challenges in the development and integration of devices based on these materials. Electrical contacts based on van der Waals (vdWs) materials can couple 2D and other materials through vdWs gaps, with charge transport dominated by quantum tunneling across the gap. Such vdWs interfaces with controlled electronic properties can reduce Fermi level pinning and avoid the formation of Schottky barriers.

Efficient quantum tunneling of electrons across vdWs contacts involves conservation of electron energy and the momentum component parallel to the interface, referred to as the transverse momentum. Approaches to achieve high-transparency vdWs contacts have focused on band energy alignment at the interface. However, the effects of momentum mismatch on carrier transport across vdWs gaps have received less attention.

When the transverse momentum distributions of charge carriers in the 2D material and the three-dimensional (3D) material differ substantially, a momentum mismatch exists at the contact interface. This momentum mismatch can impede the exchange of charge carriers between the materials, affecting the quality of the electrical contact. For example, in graphene-silicon junctions, the six-fold K/K′ valley band structure of graphene and the band structure of silicon can result in different degrees of transverse momentum mismatch depending on the doping type of the silicon.

Existing approaches to achieving ohmic contacts on 2D materials include side contacts, phase engineering, and orbital hybridization. These approaches can involve sophisticated device fabrication procedures and may be limited to specific material systems. Accordingly, there remains a need in developing approaches for constructing electrical contacts on 2D materials that address momentum mismatch considerations.

### SUMMARY

This summary is provided to introduce a selection of concepts in a simplified form that are further described below in the detailed description. This summary is not intended to identify key features or essential features of the claimed subject matter, nor is it intended to be used as an aid in determining the scope of the claimed subject matter.

According to an aspect of the present disclosure, a method of increasing electrical conductivity of a contact or interface between a two-dimensional (2D) material and a three-dimensional (3D) material is provided. The method comprises introducing metallic scattering media to reduce momentum mismatch that occurs in connection with charge carriers.

According to other aspects of the present disclosure, the method may include one or more of the following features. The metallic scattering media may be introduced where a van der Waals gap exists. The metallic scattering media may be provided at the contact or the interface. The metallic scattering media may be provided external to the 2D material on an opposite side of the 2D material from where the contact or the interface with the 3D material forms. The metallic scattering media may have a sufficiently large Fermi radius in a momentum-energy space to effectively scatter electrons and give them transverse momentum. The metallic scattering media may be in the form of metal nanoparticles or thin films, and may comprise one of gold, platinum, and copper. The 2D material may include, but is not limited to, graphene, transition metal dichalcogenides, or similar. The 3D material may include, but is not limited to, silicon or other semiconductor materials.

According to another aspect of the present disclosure, a device is provided. The device is manufactured by a method of increasing electrical conductivity of a contact or interface between a two-dimensional (2D) material and a three-dimensional (3D) material. The method comprises introducing metallic scattering media to reduce momentum mismatch that occurs in connection with charge carriers. The device improves electrical contact conductivity.

The foregoing general description of the illustrative implementations and the following detailed description thereof are merely exemplary aspects of the teachings of this disclosure and are not restrictive. This summary is not intended to identify key features or essential features of the claimed subject matter, nor is it intended to be used to limit the scope of the claimed subject matter.

### BRIEF DESCRIPTION OF FIGURES

The foregoing summary, as well as the following detailed description of illustrative implementations, is better understood when read in conjunction with the appended drawings. For the purpose of illustrating the implementations, there is shown in the drawings example constructions of the implementations; however, the implementations are not limited to the specific methods and instrumentalities disclosed. In the drawings:

FIG. 1A illustrates a tunneling junction device comprising a silicon-graphene contact region, according to aspects of the present disclosure;

FIG. 1B illustrates a fabrication workflow for a tunneling junction device, according to aspects of the present disclosure;

FIG. 1C illustrates an Atomic Force Microscopy image of a graphene layer surface, according to aspects of the present disclosure;

FIG. 2A illustrates transverse momentum distributions in silicon-graphene tunneling junctions, according to aspects of the present disclosure;

FIG. 2B illustrates band alignment diagrams for n-type and p-type silicon-graphene tunneling junctions, according to aspects of the present disclosure;

FIG. 2C illustrates temperature-dependent tunneling current for the devices of FIGS. 2A-2B, according to aspects of the present disclosure;

FIG. 2D illustrates current-voltage characteristics of silicon-graphene tunneling junctions, according to aspects of the present disclosure;

FIG. 2E illustrates first-order tunneling spectra of silicon-graphene tunneling junctions, according to aspects of the present disclosure;

FIG. 2F illustrates an energy level diagram of the p-Si-Gr junction showing phonon-assisted inelastic tunneling, according to aspects of the present disclosure;

FIG. 3A illustrates a schematic cross-sectional view of a device structure with gold nanoparticles at an interface, according to aspects of the present disclosure;

FIG. 3B illustrates a schematic representation of momentum scattering mechanisms in a tunneling junction, according to aspects of the present disclosure;

FIG. 3C illustrates current-voltage characteristics comparing devices with and without gold at an interface, according to aspects of the present disclosure;

FIG. 3D illustrates first-order tunneling spectra at multiple temperatures, according to aspects of the present disclosure;

FIG. 3E illustrates current measurements for different gold thicknesses at an interface, according to aspects of the present disclosure;

FIG. 3F illustrates first-order tunneling spectra for varying gold thicknesses, according to aspects of the present disclosure;

FIG. 4A illustrates a schematic cross-sectional view of a device with metal nanoparticle decoration, according to aspects of the present disclosure;

FIG. 4B illustrates current-voltage curves of the device of FIG. 4A, according to aspects of the present disclosure;

FIG. 4C illustrates first order tunneling spectrum of p-Si-Gr junction with gold nanoparticles outside an interface, according to aspects of the present disclosure;

FIG. 4D illustrates momentum matching in a tunneling junction with a gold electrode, according to aspects of the present disclosure;

FIG. 4E illustrates momentum matching in a tunneling junction with a platinum electrode, according to aspects of the present disclosure; and

FIG. 4F illustrates first-order tunneling spectra at multiple temperatures for a tunneling junction with platinum, according to aspects of the present disclosure.

### DETAILED DESCRIPTION

The following description sets forth exemplary aspects of the present disclosure. It should be recognized, however, that such description is not intended as a limitation on the scope of the appended claims. Rather, the description also encompasses combinations and modifications to those exemplary aspects described herein.

The present disclosure relates to methods and apparatuses for increasing electrical conductivity of contacts or interfaces between two-dimensional (2D) materials and three-dimensional (3D) materials. In some implementations, the methods and apparatus described herein may be used to form ohmic or ohmic-like van der Waals contacts between 2D materials and 3D materials.

Two-dimensional materials such as graphene and transition metal dichalcogenides are candidates for microelectronics applications, which may involve heterogeneous integration of 2D materials with 3D materials. The fabrication of ohmic contacts on 2D materials presents challenges due to the mismatch between electronic properties of 2D materials and those of both traditional metal-based and van der Waals electrodes. Van der Waals interfaces with controlled electronic properties may eliminate Fermi level pinning and avoid the formation of Schottky barriers.

Efficient quantum tunneling of electrons across van der Waals contacts may involve conservation of electron energy and momentum components parallel to the interface, referred to as transverse momentum. Prior approaches to achieving high-transparency van der Waals contacts have focused on band energy alignment at the interface, while effects of momentum mismatch on carrier transport across van der Waals gaps have been largely neglected.

The present disclosure provides methods and apparatus that address momentum mismatch between 2D materials and 3D materials at contact interfaces. In some implementations, metallic scattering media may be introduced to reduce momentum mismatch that occurs in connection with charge carriers. The metallic scattering media may provide additional momentum to compensate for the momentum mismatch, thereby enhancing junction conductivity and enabling formation of high-quality ohmic contacts.

In some implementations, the metallic scattering media may be located at the contact or interface between the 2D material and the 3D material. In some implementations, the metallic scattering media may be located external to the 2D material, on an opposite side of the 2D material from where the contact or interface with the 3D material forms. The metallic scattering media may have a sufficiently large Fermi radius in momentum-energy space to effectively scatter electrons and provide transverse momentum to the electrons.

In some implementations, the metallic scattering media may be in the form of metal nanoparticles or thin films. The metallic scattering media may comprise gold, platinum, copper, or combinations thereof. The selection of metallic scattering media may be based on the Fermi surface characteristics of the metal and the degree of momentum mismatch to be compensated.

In some implementations, the 2D materials may include graphene, transition metal dichalcogenides, or similar. The 3D materials described herein may include silicon or other similar semiconductors. The 3D materials may be doped to achieve metallic conductivity, such as heavily doped silicon with resistivity in a range of 0.001 to 0.005 Ω·cm.

The methods and apparatus described herein establish a framework for design of high-performance ohmic van der Waals contacts based on both energy and momentum matching. The approach may facilitate efficient heterogeneous integration of 2D-3D systems and development of post-CMOS architectures. In some implementations, the approach may be well-suited for back-end-of-line processes that integrate a layer of 2D material-based devices with established 3D architectures.

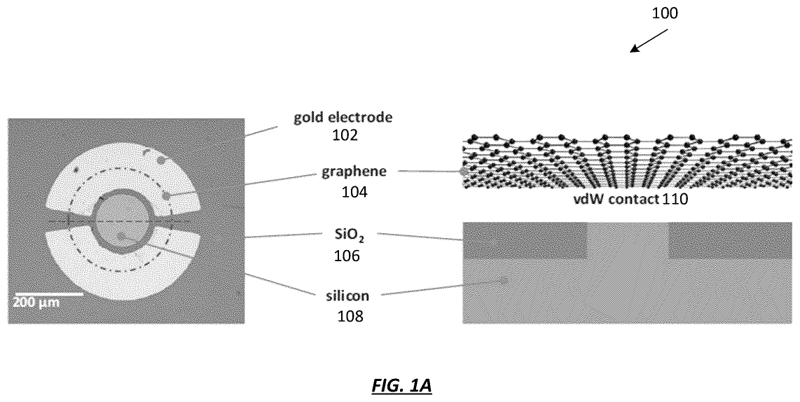

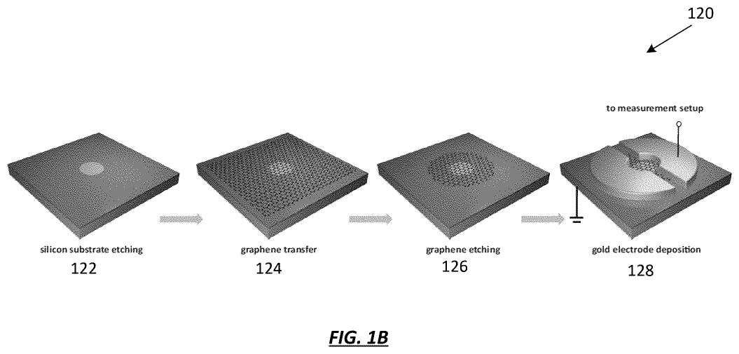

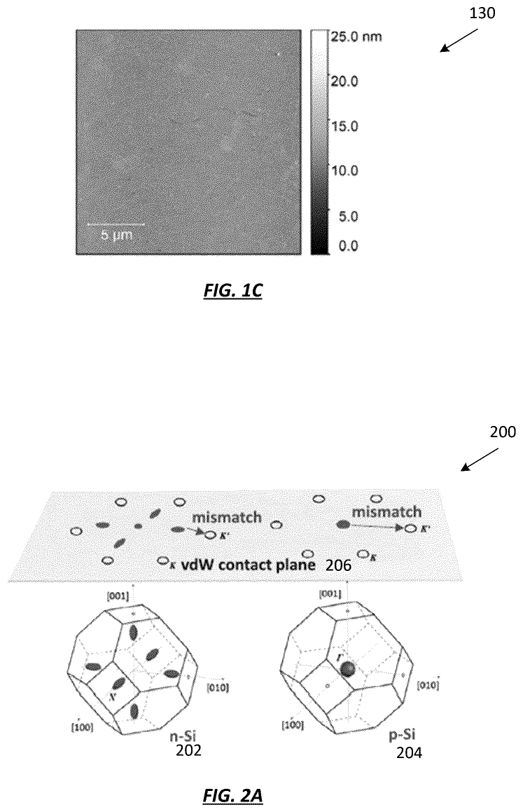

Referring to FIG. 1A, a tunneling junction device 100 is shown comprising a silicon substrate 108, a SiO₂ 106 insulating layer, a graphene layer 104, a gold electrode 102, and a van der Waals contact 110. The silicon substrate 108 may n- or p-doped to obtain distinct carrier momentum distributions at the (100)-oriented for silicon-graphene interfaces. The SiO₂ 106 insulating layer is disposed on the silicon substrate 108 and includes a circular opening that exposes a portion of the silicon substrate 108 to form a circular silicon-graphene contact region.

With continued reference to FIG. 1A, the graphene layer 104 is positioned over the SiO₂ 106 insulating layer and spans across the circular opening, forming the van der Waals contact 110 at the interface between the graphene layer 104 and the silicon substrate 108 where the SiO₂ 106 has been removed. The graphene layer 104 may be patterned into a disk shape that is slightly larger than the circular opening in the SiO₂ 106 insulating layer.

The gold electrode 102 is positioned around the perimeter of the graphene layer 104 disk. In some implementations, the gold electrode 102 may be arc-shaped and positioned around the circumference of the graphene layer 104 disk, forming side contacts with the graphene layer 104 without overlapping the silicon-graphene contact region. The arc-shaped configuration of the gold electrode 102 allows electrical connection to the graphene layer 104 while maintaining the van der Waals contact 110 between the graphene layer 104 and the silicon substrate 108 unobstructed.

As further shown in FIG. 1A, the tunneling junction device 100 provides a configuration where charge transport across the van der Waals contact 110 is dominated by quantum tunneling across the gap between the graphene layer 104 and the silicon substrate 108. The van der Waals contact 110 is formed at the interface where the graphene layer 104 directly couples with the silicon substrate 108 through a van der Waals gap, with charge transport dominated by quantum tunneling across the gap. The SiO₂ 106 insulating layer provides electrical insulation between the silicon substrate 108 and the graphene layer 104 in regions outside the circular contact region.

Referring to FIG. 1B, a tunneling junction device fabrication workflow 120 is shown for creating the tunneling junction device 100. The tunneling junction device fabrication workflow 120 includes a silicon substrate etching 122, a graphene transfer 124, a graphene etching 126, and a gold electrode deposition 128.

The tunneling junction device fabrication workflow 120 may begin with preparation of graphene by chemical vapor deposition (CVD) growth on copper foil. A copper foil may be electropolished in 80% phosphoric acid (H₃PO₄) at 8V DC power supply prior to graphene growth. The copper foil may be dried with a N₂ gun after electropolishing. The copper foil may then be inserted into a quartz tube of a CVD system and sealed. The copper foil may be annealed at 1040° C. in a supply of argon and hydrogen (Ar 90%:H₂ 10%) at 6 sccm for 20 minutes. Graphene growth may be carried out at 1040° C. by controlling methane (CH₄) flowrate at 35 sccm and a mixture of argon and hydrogen (Ar 90%: H₂ 10%) at 6 sccm for 30 minutes with pressure maintained at 540 mTorr.

With continued reference to FIG. 1B, the silicon substrate etching 122 involves selective etching of the SiO₂ 106 layer on the silicon substrate 108 using buffered hydrogen fluoride (HF) acid through photolithography. The silicon substrate etching 122 creates circular silicon contact areas that are passivated by Si—H bonds. The circular regions of the SiO₂ 106 are removed to expose the underlying silicon substrate 108.

The graphene transfer 124 follows the silicon substrate etching 122. The graphene may be transferred using a polymer-free wet transfer technique. Prior to transfer, the bottom side of the copper foil may be etched to remove unwanted graphene using RF argon plasma. The copper foil may then be etched in 0.1 M ammonium persulfate ((NH₄)₂S₂O₈) solution in an enclosed Ar environment to prevent oxidation. The etching solution may be replaced by deionized water three times, resulting in free-floating graphene ready for transfer. The graphene transfer 124 may be performed immediately after the silicon substrate etching 122 and before the passivated silicon contact areas become re-oxidized, allowing the graphene layer 104 to be transferred onto the treated silicon substrate 108 to obtain silicon-graphene contacts in the etched area.

As further shown in FIG. 1B, the tunneling junction device fabrication workflow 120 includes post-transfer annealing. After the graphene transfer 124, the devices may be annealed at 300° C. in 200 mTorr of H₂/N₂ environment for 60 minutes.

The graphene etching 126 follows the post-transfer annealing. The graphene etching 126 involves patterning the continuous graphene films into isolated disks using photolithography and Argon plasma etching. The graphene layer 104 may be patterned into disks with diameter larger than the circular silicon contact areas, such that the graphene layer 104 covers the silicon-graphene contact region and extends onto the surrounding SiO₂ 106 layer.

The gold electrode deposition 128 completes the tunneling junction device fabrication workflow 120. The gold electrode 102 may be fabricated by thermal deposition of a 5 nm chromium (Cr) adhesion layer followed by 45 nm of gold (Au). The deposited metal layers may be patterned by lift off in acetone to form two arc-shaped gold electrodes around the circumference of the graphene layer 104 disks. The gold electrode 102 forms side contacts with the graphene layer 104 without overlapping the silicon contact areas. After the gold electrode deposition 128, the tunneling junction device 100 is ready for connection to a measurement setup.

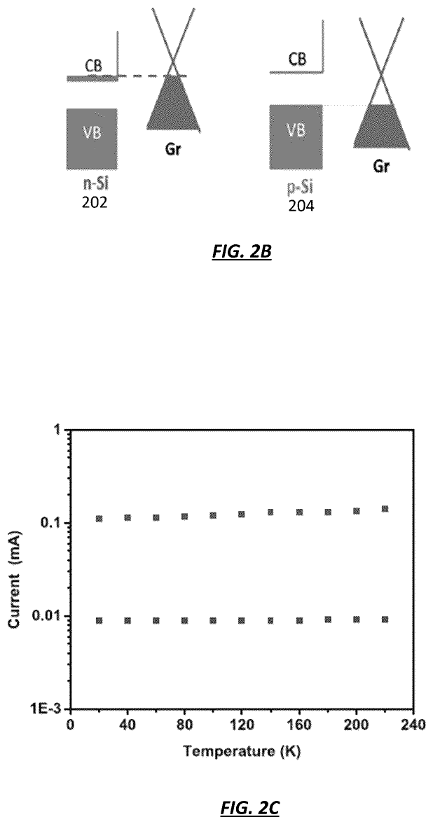

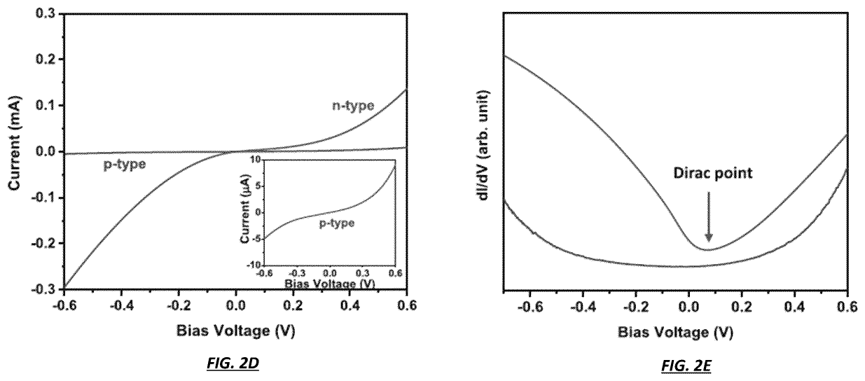

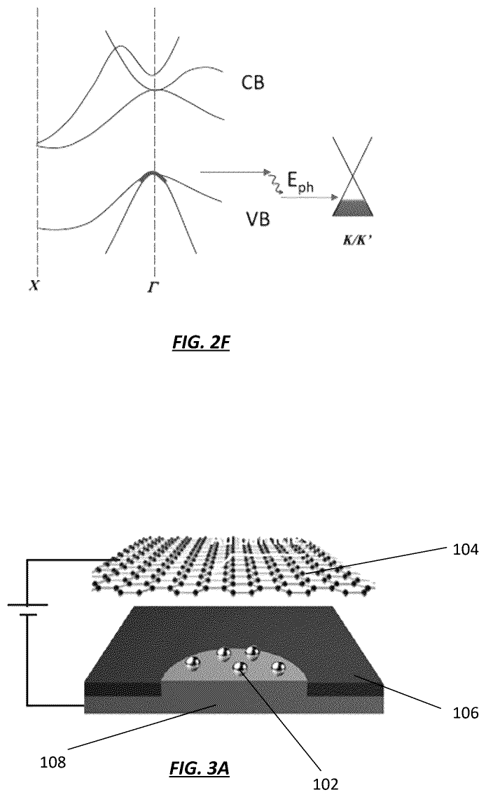

Referring to FIGS. 1C and 2A, an Atomic Force Microscopy (AFM) image 130 and transverse momentum distributions 200 in silicon-graphene tunneling junctions are shown. The AFM image 130 depicts a surface topography of the graphene layer 104 with a scale bar of 5 μm and a height scale ranging from 0.0 to 25.0 nm. The AFM image 130 indicates a clean flat surface of the graphene layer 104 following the tunneling junction device fabrication workflow 120, confirming that the polymer-free wet transfer technique and post-transfer annealing yield ultra-flat and clean interfaces.

With continued reference to FIGS. 1C and 2A, the transverse momentum distributions 200 illustrate momentum mismatch between silicon and graphene at a vdW contact plane 206. The silicon substrate 108 may be either n-type or p-type doped silicon, with resistivity of 0.001-0.005 Ω·cm placing the silicon substrate 108 in the metallic regime. The choice of n-type or p-type doping results in two distinct carrier momentum distributions at the (100)-oriented silicon-graphene interfaces.

As further shown in FIGS. 1C and 2A, n-Si-Gr tunneling junctions 202 are depicted on the left side of the transverse momentum distributions 200 with elliptical Fermi surface projections in the [001], [010], and [100] crystallographic directions. The elliptical Fermi surface projections represent the transverse momentum components of n-type silicon, which originate from the X-valleys in the silicon band structure. The n-Si-Gr tunneling junctions 202 exhibit a smaller transverse momentum mismatch from the X-valleys in silicon to the K/K′ valleys in graphene.

With continued reference to FIGS. 1C and 2A, p-Si-Gr tunneling junctions 204 are depicted on the right side of the transverse momentum distributions 200 with a circular Fermi surface projection at the center. The circular Fermi surface projection represents the transverse momentum components of p-type silicon, which originate from the Γ-point in the silicon band structure. The p-Si-Gr tunneling junctions 204 exhibit a larger transverse momentum mismatch from the Γ-point in silicon to the K/K′ valleys in graphene compared to the n-Si-Gr tunneling junctions 202.

Both the n-Si-Gr tunneling junctions 202 and the p-Si-Gr tunneling junctions 204 display momentum mismatch arrows pointing toward the K and K′ valleys of graphene at the vdW contact plane 206. The graphene layer 104 may be p-type doped with the Fermi level below the Dirac point, as indicated by a V-shaped feature in tunneling spectra at 70 mV. The different transverse momentum components projected on the tunneling junction interfaces for n-type versus p-type silicon wafers result in different momentum mismatch magnitudes with the K/K′ valleys of graphene, which may affect quantum tunneling efficiency across the van der Waals contact 110.

Referring to FIG. 2B, band alignment diagrams for n-Si-Gr tunneling junctions 202 and p-Si-Gr tunneling junctions 204 are shown. The band alignment diagrams illustrate the energy band relationships at the interface between silicon and graphene for both n-type and p-type doping configurations. The n-Si-Gr tunneling junctions 202 are depicted on the left side of the figure. The n-Si-Gr tunneling junctions 202 show the conduction band (CB) and valence band (VB) of n-type silicon aligned with the Dirac cone band structure of graphene. A dashed line indicates the Fermi level position in the n-Si-Gr tunneling junctions 202, where the Fermi level is positioned near the conduction band of the n-type silicon. The graphene band structure is represented by a characteristic X-shaped Dirac cone, with the Fermi level intersecting the Dirac cone below the Dirac point, indicating p-type doping in the graphene layer.

The p-Si-Gr tunneling junctions 204 are depicted on the right side of the figure. The p-Si-Gr tunneling junctions 204 show the conduction band (CB) and valence band (VB) of p-type silicon aligned with the Dirac cone band structure of graphene. The Fermi level in the p-Si-Gr tunneling junctions 204 is positioned closer to the valence band of the p-type silicon compared to the n-Si-Gr tunneling junctions 202. When the graphene layer is in contact with p-type silicon, the Fermi level of the graphene may move further down from the Dirac point to align with the valence band maximum of silicon.

With continued reference to FIG. 2B, both the n-Si-Gr tunneling junctions 202 and the p-Si-Gr tunneling junctions 204 may be treated as metal-to-metal contacts because graphene is a semi-metal and the silicon used in the tunneling junction device 100 is heavily doped to achieve metallic conductivity. In such metal-to-metal contact configurations, the band matching condition for energy conservation may be satisfied, which simplifies interpretation of electronic transport data in terms of effects of momentum mismatch rather than band alignment effects.

The band alignment diagrams in FIG. 2B indicate that the density of states in the graphene layer may be larger in the p-Si-Gr tunneling junctions 204 due to the lower Fermi level position relative to the Dirac point. However, experimental observations may show that the p-Si-Gr tunneling junctions 204 exhibit lower conductivity than the n-Si-Gr tunneling junctions 202, which suggests that band alignment alone does not account for the differences in junction conductivity. The transverse momentum mismatch between the silicon substrate 108 and the graphene layer at the van der Waals contact 110 may be a dominant factor affecting quantum tunneling efficiency across the interface.

Referring to FIG. 2D, current-voltage (IV) curves for n-type and p-type silicon-graphene tunneling junctions are shown. The IV curves plot current in milliamps (mA) on the vertical axis against bias voltage in volts (V) on the horizontal axis, with the bias voltage ranging from approximately −0.6 V to 0.6 V. The measurements were obtained at 5 K to minimize thermal effects on the tunneling characteristics. The curve representing the n-type silicon-graphene junction exhibits current values reaching approximately 0.3 mA at positive bias and −0.3 mA at negative bias. The curve representing the p-type silicon-graphene junction shows substantially lower current values compared to the n-type junction. The tunneling current for the n-type silicon-graphene junction is two orders of magnitude larger than for the p-type silicon-graphene junction. FIG. 2C illustrates temperature-dependent tunneling current measured at the bias of 0.6 V. In FIG. 2C, the upper plot shows the n-Si-Gr device 202 whereas the lower plot shows the p-Si-Gr device 204. Referring again to FIG. 2D, an inset graph displays a magnified view of the p-type device IV curve with current measured in microamps (μA), showing the current ranging from approximately −10 μA to 10 μA over the same bias voltage range.

The two orders of magnitude difference in tunneling current between the n-type and p-type silicon-graphene junctions may be attributed to the smaller transverse momentum mismatch in the n-type junction. In the n-type silicon-graphene junction, charge carriers tunnel from the X-valleys in silicon to the K/K′ valleys in graphene, which involves a smaller transverse momentum mismatch. In the p-type silicon-graphene junction, charge carriers tunnel from the Γ-point in silicon to the K/K′ valleys in graphene, which involves a larger transverse momentum mismatch. The larger momentum mismatch in the p-type junction suppresses quantum tunneling efficiency, resulting in lower tunneling current.

Referring to FIG. 2E, first-order tunneling spectra are shown plotting differential conductance (dI/dV) in arbitrary units on the vertical axis against bias voltage in volts (V) on the horizontal axis. The tunneling spectra reflect carrier energy-dependent tunneling probability across the silicon-graphene interface. The curve corresponding to the n-type silicon-graphene junction exhibits a V-shaped feature with a minimum identified as the Dirac point. The Dirac point is indicated by an arrow at approximately 70 mV bias, which indicates p-type doping in the graphene layer with the Fermi level positioned below the Dirac point. The V-shaped feature in the tunneling spectrum of the n-type silicon-graphene junction is consistent with the density of states profile of graphene near the Dirac point. The curve corresponding to the p-type silicon-graphene junction and displays a relatively flat, featureless response across the bias voltage range from approximately −0.6 V to 0.6 V. The almost flat curve with low conductance in the bias range from −0.4 V to 0.4 V exhibited by the p-type silicon-graphene junction indicates that quantum tunneling is suppressed due to the large momentum mismatch between the Γ-point in p-type silicon and the K/K′ valleys in graphene. The absence of the Dirac point feature in the p-type junction spectrum may be attributed to smearing of spectroscopic features by inelastic tunneling processes.

The p-type silicon-graphene junction spectrum shows a gradual increase in differential conductance at higher positive and negative bias values. As the bias voltage increases, the potential drop between graphene and silicon may become resonant with phonon modes whose momenta compensate for the difference between the transverse momenta in graphene and silicon, enabling phonon-assisted inelastic tunneling. FIG. 2F illustrates an energy level diagram of the p-Si-Gr junction showing phonon-assisted inelastic tunneling. The rapid increase of differential conductivity in the tunneling spectrum at large bias for the p-type junction is manifested by phonon-assisted tunneling that provides momentum compensation for the large mismatch between the Γ-point and the K/K′ valleys.

The tunneling spectra in FIG. 2E exclude the possibility that the large difference in conductance between the n-type and p-type junctions originates from different band alignments. If band alignment change were the main mechanism, the p-type junction would exhibit a V-shaped feature with a shifted position rather than a featureless spectrum. The observed differences in the tunneling spectra support the interpretation that transverse momentum mismatch dominates the electronic properties of the silicon-graphene van der Waals contacts.

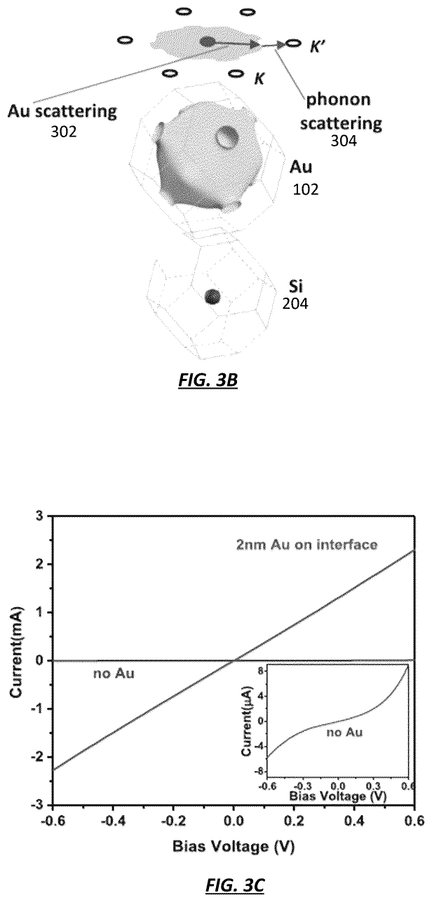

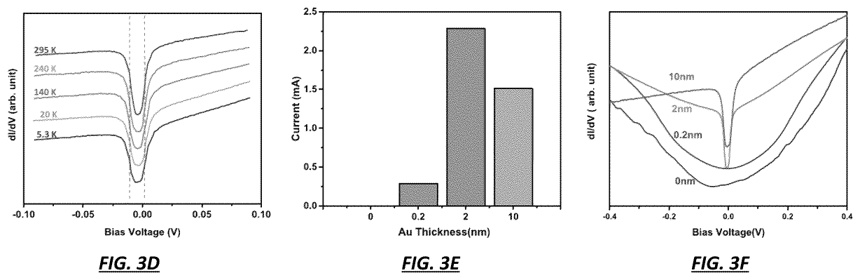

Referring to FIG. 3A, a schematic cross-sectional view of the tunneling junction device 100 with gold nanoparticles at the silicon-graphene interface is shown. The tunneling junction device 100 includes the silicon substrate 108 at the base, with a curved recess or opening formed in an upper surface of the silicon substrate 108. The SiO₂ 106 is disposed on top of the silicon substrate 108, surrounding the curved recess and providing electrical insulation between the silicon substrate 108 and a graphene layer 104 in regions outside the contact area.

Gold nanoparticles 102 are positioned within the curved recess between the silicon substrate 108 and the graphene layer 104. The gold nanoparticles serve as scattering centers at the interface to compensate for momentum mismatch between the silicon substrate 108 and the graphene layer 104. The graphene layer 104 is illustrated as a lattice structure spanning across the top of the tunneling junction device 100, covering both the SiO₂ 106 and the recess containing the gold nanoparticles. The gold electrode 102 is connected to the structure and shown on the left side of the figure with electrical connection lines extending from the gold electrode 102.

The gold nanoparticles 102 are introduced at the interface based on work function matching considerations. Gold has a work function of 5.38 eV, which is close to the energy level of the silicon valence band top at 5.17 eV. The silicon valence band top energy of 5.17 eV is calculated from the electron affinity of silicon (4.05 eV) plus the bandgap of silicon (1.12 eV). The proximity of the gold work function to the silicon valence band top energy enables formation of an ohmic contact between gold and p-type silicon. The introduction of gold nanoparticles 102 at the interface may not significantly change the Fermi level in p-type silicon due to the work function matching between gold and the silicon valence band.

The gold nanoparticles 102 at the interface provide elastic scattering that reduces the transverse momentum mismatch for charge carriers tunneling between the silicon substrate 108 and the graphene layer 104. Gold has a large Fermi radius, which enables the gold nanoparticles to scatter electrons elastically and provide transverse momentum to compensate for the momentum mismatch between the Γ-point of p-type silicon and the K/K′ valleys of graphene. The configuration shown in FIG. 3A allows charge transport across the van der Waals contact 110 to be enhanced by the momentum-compensating scattering provided by the gold nanoparticles at the interface.

Referring to FIGS. 3B-3C, momentum scattering mechanisms in a p-Si-Gr tunneling junction 204 with interfacial gold conditioning are shown. The p-Si-Gr tunneling junction 204 includes a gold electrode 102 positioned at the interface between p-type silicon and graphene to provide scattering centers for momentum compensation. The upper portion of FIGS. 3B-3C shows a momentum space diagram with K and K′ valley points of graphene, where a charge carrier undergoes scattering processes to overcome the transverse momentum mismatch.

A gold (Au) scattering 302 mechanism is indicated by an arrow pointing toward the K′ point in the momentum space diagram. The gold (Au) scattering 302 represents elastic scattering provided by the gold electrode 102 at the interface. The gold Fermi surface has a radius of approximately 1.36 Å⁻¹, while the K/K′ points of graphene are positioned 1.70 Å⁻¹ from the Γ point in momentum space. The difference between the graphene K/K′ valley position and the largest transverse Fermi-surface momentum component in gold results in a momentum mismatch of approximately 0.34 Å⁻¹.

A phonon scattering 304 mechanism is depicted as another arrow in the momentum space diagram. The phonon scattering 304 represents inelastic scattering that provides additional momentum compensation toward the K/K′ valleys of graphene. The phonon scattering 304 enables phonon-assisted inelastic tunneling when the bias voltage exceeds the phonon energy, allowing charge carriers to acquire the remaining momentum needed to reach the K/K′ valleys after elastic scattering by the gold electrode 102.

The gold electrode 102 is depicted as a yellow irregular spherical structure positioned above the p-Si-Gr tunneling junction 204. The p-Si-Gr tunneling junction 204 is represented as a polyhedral structure below the gold electrode 102 in the schematic. The combination of the gold (Au) scattering 302 and the phonon scattering 304 provides a two-step momentum compensation mechanism that enables charge carriers to tunnel efficiently from the Γ-point of p-type silicon to the K/K′ valleys of graphene.

As show in FIG. 3C, a lower graph displays current-voltage (IV) characteristics comparing devices with and without gold at the interface. A curve labeled “2 nm Au on interface” demonstrates a linear ohmic-like response with current reaching approximately 2.5 mA at 0.6 V bias. A curve labeled “no Au” shows substantially lower current levels for the device without gold conditioning at the interface. An inset magnifies the IV curve for the device without gold, showing current in the microampere range.

The introduction of the gold electrode 102 at the interface enhances the junction conductivity by more than three orders of magnitude compared to the p-Si-Gr tunneling junction 204 without interfacial conditioning. The linear IV characteristics exhibited by the gold-conditioned junction indicate formation of an ohmic-like contact between the p-type silicon and graphene. The current enhancement from the microampere range to the milliampere range demonstrates that the gold (Au) scattering 302 and the phonon scattering 304 mechanisms effectively compensate for the 0.34 Å⁻¹ momentum mismatch between the gold Fermi surface and the graphene K/K′ valleys, enabling efficient quantum tunneling across the van der Waals contact 110.

Referring to FIG. 3D, first-order tunneling spectra are shown for a p-type silicon-graphene junction with 2 nm gold nanoparticles at the interface, measured at multiple temperatures including 5.3 K, 20 K, 140 K, 240 K, and 295 K. The tunneling spectra plot differential conductance (dI/dV) in arbitrary units against bias voltage ranging from approximately −0.10 V to 0.10 V. A narrow and sharp gap-like feature appears in the spectra with a width of approximately 12 mV. The gap-like feature is indicated by dashed lines in FIG. 3D and is associated with phonon-assisted inelastic tunneling across the gold-graphene interface.

The width of the gap-like feature in FIG. 3D remains independent of temperature across the measured temperature range from 5.3 K to 295 K. The temperature independence of the gap width indicates that spontaneous phonon emission processes dominate inelastic tunneling over the entire studied temperature range. The lack of temperature dependence confirms that the gap feature does not originate from band alignment effects, which would result in spectroscopic broadening by the Fermi distribution with broadening of kBT/e up to 25 mV at T=295 K that would substantially suppress the gap feature. The gap-like feature results from the onset of phonon generation once bias exceeds the phonon energy of approximately 6 meV, as inferred from the width of the gap. Analysis of phonon dispersion relations of graphene and gold indicates that the out-of-plane acoustic (ZA) phonon of graphene facilitates phonon-assisted inelastic tunneling. The ZA phonon mode may dominate due to a strong dependence of tunneling probability on the van der Waals gap width modulated by the ZA mode. The phonon-assisted tunneling mechanism provides momentum compensation for the approximately 0.34 Å⁻¹ mismatch between the gold Fermi surface radius of approximately 1.36 Å⁻¹ and the graphene K/K′ valley position of 1.70 Å⁻¹ from the Γ point.

Referring to FIG. 3E, a bar chart displays current in milliamps measured at 0.5 V bias for different gold thicknesses of 0 nm, 0.2 nm, 2 nm, and 10 nm deposited on the silicon surface before graphene transfer. The current increases from the microampere range for the 0 nm gold thickness to the milliampere range with the introduction of gold nanoparticles at the interface. The 2 nm gold thickness exhibits the highest current level among the tested thicknesses, while the 10 nm gold thickness exhibits a slightly lower current level than the 2 nm thickness. The 2 nm thick gold forms isolated nanoparticles that do not form a continuous conductive film, as the gold thickness is insufficient to create a continuous and conductive layer. The 10 nm thick gold forms a continuous film across the silicon surface. The difference in current levels between the 2 nm and 10 nm gold thicknesses may be attributed to differences in momentum matching characteristics arising from the film morphology.

Quantum confinement in the gold nanoparticles formed by the 2 nm deposition results in broadening of the momentum distribution according to the uncertainty relationship Δk≈1/Δx, where Δx is the nanoparticle size. The momentum broadening from quantum confinement in the isolated nanoparticles reduces the effective momentum mismatch between the gold Fermi surface and the graphene K/K′ valleys. The continuous film formed by the 10 nm gold deposition does not exhibit the same degree of momentum broadening, resulting in a larger effective momentum mismatch and a wider phonon gap that reduces the current level compared to the 2 nm case.

Referring to FIG. 3F, first-order tunneling spectra are shown for p-type silicon-graphene junctions with varying gold thicknesses of 0 nm, 0.2 nm, 2 nm, and 10 nm between the silicon and graphene layers. The tunneling spectra plot differential conductance (dI/dV) in arbitrary units against bias voltage ranging from approximately −0.4 V to 0.4 V. The spectral features change with different amounts of gold interface conditioning, reflecting the different momentum matching characteristics associated with each gold thickness. The 0 nm gold thickness spectrum curve exhibits a flat, featureless response consistent with suppressed quantum tunneling due to the large momentum mismatch between the Γ-point of p-type silicon and the K/K′ valleys of graphene. The 2 nm gold thickness spectrum curve and the 10 nm gold thickness spectrum curve both exhibit the gap-like feature associated with phonon-assisted inelastic tunneling, with the 10 nm sample exhibiting a larger gap width than the 2 nm sample by approximately 10 meV. The 0.2 nm gold thickness spectrum curve does not exhibit a well-defined sharp gap feature present in the 2 nm and 10 nm cases. The 0.2 nm gold thickness corresponds to isolated clusters of a few atoms, with a characteristic dimension that corresponds to approximately 0.5 Å⁻¹ wavevector uncertainty. The 0.5 Å⁻¹ wavevector uncertainty completely eliminates the momentum mismatch of 0.34 Å⁻¹ between the gold Fermi surface and the graphene K/K′ valleys. Because the momentum mismatch is eliminated by the quantum confinement-induced momentum broadening, phonon-assisted momentum matching is not required for tunneling in the 0.2 nm case, and the phonon gap does not appear in the spectrum. However, the fewer scattering centers provided by the 0.2 nm gold deposition result in a lower current level compared to the 2 nm case, as shown in FIG. 3E.

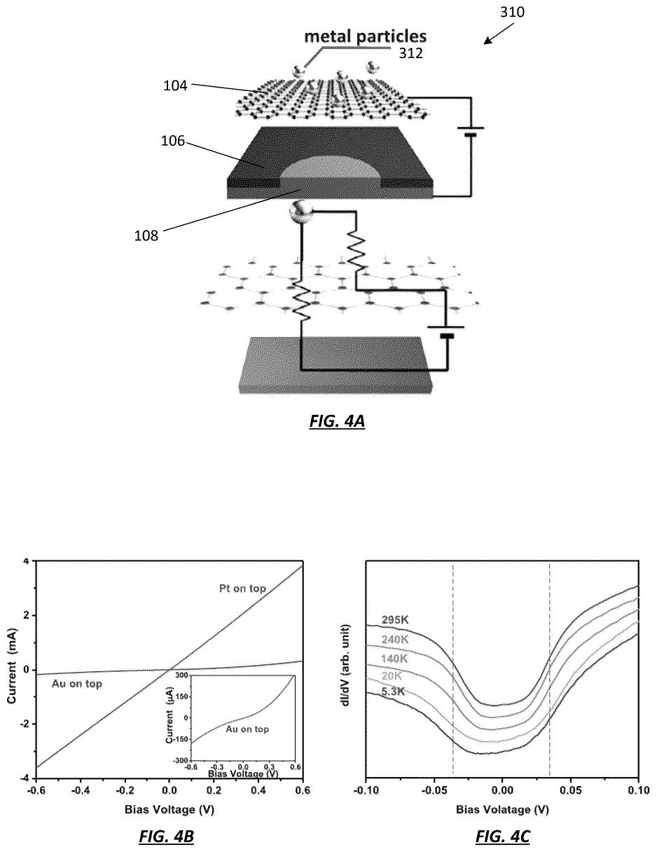

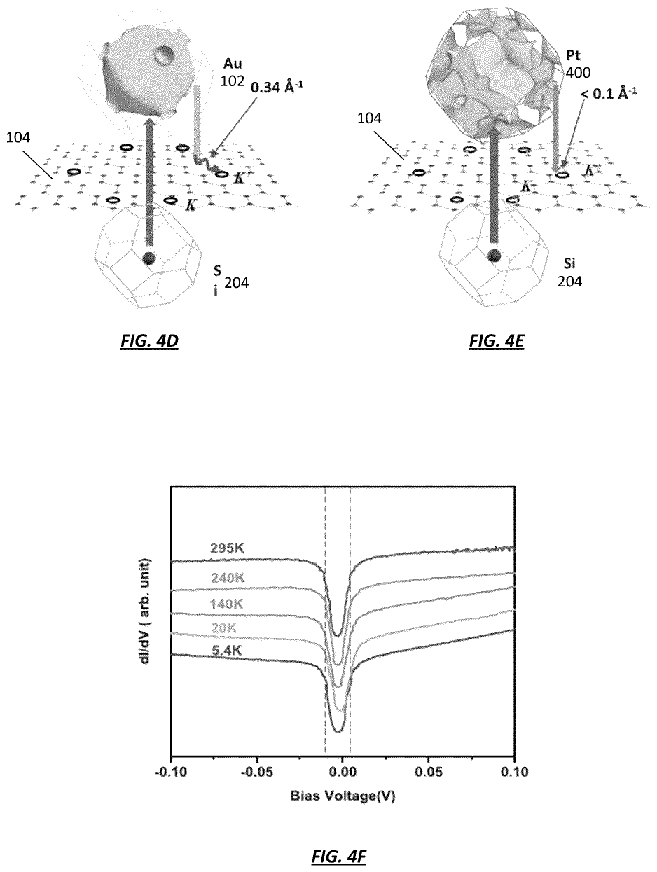

Referring to FIGS. 4A-4C, a device 310 with a metal nanoparticle 312 decoration at a silicon-graphene interface is shown. The device 310 includes the silicon substrate 108 at the bottom, with the SiO₂ 106 layer positioned above the silicon substrate 108. The SiO₂ 106 layer has an opening that exposes a portion of the silicon substrate 108 to form a contact region. The graphene layer 104 is positioned above the SiO₂ 106 layer and spans across the opening, forming a contact region with the silicon substrate 108.

Metal nanoparticles 312 are deposited at the interface between the silicon substrate 108 and the graphene layer 104 within the opening of the SiO₂ 106 layer. The metal nanoparticles 312 serve as a scattering center to compensate for momentum mismatch between the silicon substrate 108 and the graphene layer 104. The metal nanoparticles 312 may be positioned at different locations relative to the graphene layer 104 and the silicon substrate 108. In some implementations, the metal nanoparticles 312 may be deposited at the silicon-graphene interface within the opening of the SiO₂ 106 layer, as depicted in the device 310. In some implementations, the metal nanoparticles 312 may be deposited on an exposed graphene surface external to the interface, on an opposite side of the graphene layer 104 from where the contact with the silicon substrate 108 forms. The external placement of the metal nanoparticles 312 on the exposed graphene surface provides an alternative configuration for introducing scattering centers that compensate for momentum mismatch without positioning the metal nanoparticles 312 directly within the van der Waals contact 110 region.

The placement location of the metal nanoparticles 312 may affect the charge transport mechanism across the device 310. When the metal nanoparticles 312 are positioned at the interface between the silicon substrate 108 and the graphene layer 104, charge carriers may undergo scattering by the metal nanoparticle 312 during tunneling across the van der Waals gap. When the metal nanoparticles 312 are positioned on the exposed graphene surface external to the interface, charge carriers may first pass through the graphene layer 104 before interacting with the metal nanoparticles 312, resulting in a two-step charge transfer process. Both placement configurations enable the metal nanoparticles 312 to provide momentum compensation for charge carriers tunneling between the silicon substrate 108 and the graphene layer 104.

As also shown in FIG. 4A, the device 310 may be represented by effective resistors for electrical characterization of the tunneling junction. FIG. 4B illustrates current-voltage (I-V) curves of the device of FIG. 4A. In FIG. 4B, the curve labeled “Au on top” represents the I-V curve with 2 nm gold on top and the curve “Pt on top” represents I-V curve with 2 nm platinum on top. The inset shows the magnified I-V curve of device of FIG. 4A with 2 nm gold on top. FIG. 4C illustrates first order tunneling spectrum of p-Si-Gr junction with gold nanoparticles outside the interface.

Referring to FIGS. 4D-4F, a comparison of momentum matching characteristics between the gold electrode 102 and platinum 400 in p-Si-Gr tunneling junctions 204 is shown. The p-Si-Gr tunneling junctions 204 include a graphene layer 104 disposed on p-type silicon, with metal electrodes positioned on an exposed surface of the graphene layer 104 external to the silicon-graphene interface. The external placement of metal electrodes on the graphene layer 104 provides scattering centers for momentum compensation without positioning the metal directly within the van der Waals contact 110 region.

FIG. 4D depicts the gold electrode 102 positioned above the graphene layer 104 in the p-Si-Gr tunneling junctions 204. The gold electrode 102 exhibits a momentum mismatch of 0.34 Å⁻¹ relative to the K and K′ valleys of the graphene layer 104. The momentum mismatch of 0.34 Å⁻¹ arises from the difference between the gold Fermi surface radius of approximately 1.36 Å⁻¹ and the graphene K/K′ valley position of 1.70 Å⁻¹ from the Γ point in momentum space.

FIG. 4E depicts platinum 400 positioned above the graphene layer 104 in the p-Si-Gr tunneling junctions 204. The platinum 400 exhibits a smaller momentum mismatch of less than 0.1 Å⁻¹ relative to the K and K′ valleys of the graphene layer 104. The platinum 400 has a larger Fermi surface than the gold electrode 102, which results in the smaller momentum mismatch between the platinum Fermi surface and the graphene K/K′ valleys. The larger Fermi surface of the platinum 400 reduces the dependence on phonon-assisted processes for momentum compensation during tunneling.

External decoration of the graphene layer 104 with metal nanoparticles involves a two-step tunneling process for charge transport across the p-Si-Gr tunneling junctions 204. In the two-step tunneling process, tunneling electrons driven by an electric bias first pass through the graphene layer 104 onto the metal particles positioned on the exposed graphene surface. The charge accumulation on the metal particles produces an electrical field between the graphene layer 104 and the metal particles, which results in phonon-assisted tunneling of the electrons back into the graphene layer 104. The two-step tunneling process includes a first step involving a wider tunneling barrier compared to configurations where metal nanoparticles are positioned directly at the silicon-graphene interface.

FIG. 4F displays first-order tunneling spectra (dI/dV versus Bias Voltage) measured at temperatures of 5.4 K, 20 K, 140 K, 240 K, and 295 K for the p-Si-Gr tunneling junctions 204 with external platinum 400 decoration. Dashed lines in FIG. 4F indicate a pseudo-gap feature associated with phonon-assisted inelastic tunneling. The larger Fermi surface of the platinum 400 results in a narrower phonon gap in the tunneling spectra compared to external gold electrode 102 decoration. The narrower phonon gap for the platinum 400 configuration reflects the smaller momentum mismatch of less than 0.1 Å⁻¹ that reduces the phonon energy required for momentum compensation during tunneling.

External platinum 400 decoration on the graphene layer 104 surface results in higher current than external gold electrode 102 decoration due to the larger Fermi surface and smaller momentum mismatch of the platinum 400. The current for the externally platinum-decorated junction is higher than that for the externally gold-decorated junction, and the IV curve for the platinum-decorated junction exhibits linear characteristics indicating ohmic-like contact formation. The observed differences between the effects of platinum 400 and gold electrode 102 decoration confirm that tunneling efficiency depends on the momentum mismatch between the metal Fermi surface and the graphene K/K′ valleys. Minimizing the momentum mismatch by selecting metals with larger Fermi surfaces, such as the platinum 400, maximizes the contact transparency across the van der Waals contact 110.

Thus, the methods and apparatus described herein presents an effective approach for the design of van der Waals contacts in cases when transverse momentum matching cannot be intrinsically achieved. By introducing elastic scattering centers, such as gold and platinum, the momentum mismatch between p-type silicon and graphene is minimized and contact current enhancement of more than three orders of magnitude is demonstrated. The present disclosure further describes the construction of high-performance 2D contacts, and approaches for the development of 2D-3D heterogeneous integrated microelectronics.

Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims.

What is claimed:

1. A method of increasing electrical conductivity of a contact between a two-dimensional (2D) material and a three-dimensional (3D) material, comprising:
introducing metallic scattering media at an interface between the 2D material and the 3D material, wherein the metallic scattering media reduces momentum mismatch between charge carriers in the 2D material and charge carriers in the 3D material by providing transverse momentum to the charge carriers during quantum tunneling across a van der Waals gap at the interface.

2. The method of claim 1, wherein the metallic scattering media comprises metal nanoparticles.

3. The method of claim 2, wherein the metal nanoparticles have a thickness in a range of 0.2 nm to 10 nm.

4. The method of claim 3, wherein the metal nanoparticles form isolated nanoparticles that exhibit quantum confinement effects resulting in broadening of a momentum distribution.

5. The method of claim 1, wherein the metallic scattering media comprises a metal having a Fermi radius sufficiently large to scatter electrons elastically and provide transverse momentum to compensate for the momentum mismatch.

6. The method of claim 5, wherein the metallic scattering media comprises one of gold, platinum and copper.

7. The method of claim 6, wherein the metallic scattering media comprises platinum, wherein platinum has a larger Fermi surface than gold such that a momentum mismatch between the platinum and K/K′ valleys of the 2D material is less than 0.1 Å⁻¹.

8. The method of claim 1, wherein the 2D material comprises graphene having a six-fold K/K′ valley band structure, and
wherein the 3D material comprises p-type silicon having charge carriers at a Γ-point, such that the momentum mismatch between the Γ-point of the p-type silicon and the K/K′ valleys of the graphene is compensated by the metallic scattering media.

9. The method of claim 1, wherein introducing the metallic scattering media at the interface increases a tunneling current across the van der Waals gap by more than three orders of magnitude compared to the contact without the metallic scattering media.

10. A device, comprising:
a three-dimensional (3D) substrate;
a two-dimensional (2D) material layer disposed over the 3D substrate, wherein a van der Waals contact is formed at an interface between the 2D material layer and the 3D substrate; and
metallic scattering media positioned to reduce momentum mismatch between charge carriers in the 2D material layer and charge carriers in the 3D substrate,
wherein the metallic scattering media has a Fermi radius sufficient to scatter electrons and provide transverse momentum to compensate for the momentum mismatch.

11. The device of claim 10, wherein the metallic scattering media is positioned at the interface between the 2D material layer and the 3D substrate within a van der Waals gap.

12. The device of claim 10, wherein the metallic scattering media is positioned on an exposed surface of the 2D material layer external to the interface, on an opposite side of the 2D material layer from where the van der Waals contact with the 3D substrate is formed.

13. The device of claim 10, wherein the metallic scattering media comprises metal nanoparticles having a thickness in a range of 0.2 nm to 10 nm.

14. The device of claim 13, wherein the metal nanoparticles form isolated nanoparticles exhibiting quantum confinement effects that result in broadening of a momentum distribution according to an uncertainty relationship.

15. The device of claim 10, wherein:
the 2D material layer comprises graphene having a six-fold K/K′ valley band structure; and
the 3D substrate comprises p-type silicon having charge carriers at a Γ-point, wherein the metallic scattering media compensates for a momentum mismatch between the Γ-point of the p-type silicon and the K/K′ valleys of the graphene.

16. The device of claim 15, wherein the metallic scattering media comprises platinum having a Fermi surface larger than gold such that a momentum mismatch between the platinum and the K/K′ valleys of the graphene is less than 0.1 Å⁻¹.

17. A method of fabricating an ohmic van der Waals contact between a two-dimensional (2D) material and a three-dimensional (3D) material, comprising:
providing a 3D substrate having an exposed contact region;
depositing metallic scattering media on the exposed contact region of the 3D substrate; and
transferring a 2D material layer onto the 3D substrate such that the 2D material layer covers the exposed contact region and the metallic scattering media is positioned at an interface between the 2D material layer and the 3D substrate,
wherein the metallic scattering media compensates for transverse momentum mismatch between the 2D material layer and the 3D substrate.

18. The method of claim 17, wherein providing the 3D substrate having the exposed contact region comprises:
selectively etching an insulating layer on the 3D substrate using buffered hydrogen fluoride acid through photolithography to create the exposed contact region; and
passivating the exposed contact region with Si—H bonds.

19. The method of claim 18, wherein depositing the metallic scattering media comprises thermally depositing metal nanoparticles having a thickness in a range of 0.2 nm to 10 nm on the exposed contact region before the passivated exposed contact region becomes re-oxidized.

20. The method of claim 19, further comprising annealing at 300° C. in an H₂/N₂ environment after transferring the 2D material layer onto the 3D substrate.
